(19) United States
(12) Patent Application Publication
(10) Pub. No.: US 2024/0423098 A1
(43) Pub. Date: Dec. 19, 2024

(54) Spin Orbital Squared (SO-SO) Logic

(71) Applicants: Western Digital Technologies, Inc., San Jose, CA (US); Tokyo Institute of Technology, Tokyo (JP)

(72) Inventors: Quang LE, San Jose, CA (US); Xiaoyong LIU, San Jose, CA (US); Brian R. YORK, San Jose, CA (US); Cherngye HWANG, San Jose, CA (US); Hisashi TAKANO, Fujisawa-shi (JP); Nam Hai PHAM, Tokyo (JP)

(73) Assignee: Western Digital Technologies, Inc., San Jose, CA (US)

(21) Appl. No.: 18/645,189

(22) Filed: Apr. 24, 2024

Related U.S. Application Data
(60) Provisional application No. 63/521,306, filed on Jun. 15, 2023.

(51) Int. Cl. H10N 50/85; H03K 19/18; H10N 52/80

(52) U.S. Cl. CPC H10N 50/85; H03K 19/18; H10N 52/80

(57) ABSTRACT

The present disclosure generally relate to an integrated circuit utilizing spin orbital-spin orbital (SO-SO) logic. The integrated circuit comprises a plurality of SO-SO logic cells, where each SO-SO logic cell comprises a first spin orbit torque (SOT1) layer, a second spin orbit torque (SOT2) layer, and a ferromagnetic layer disposed between the SOT1 and SOT2 layer. Each SO-SO logic cell is configured for: a first current path that is in plane to a plane of the SOT1 layer, and a second current path that is perpendicular to a plane of the SOT2 layer, the second current path being configured to extend into the ferromagnetic layer. The integrated circuit further comprises a common voltage source connected to each SOT device, and one or more interconnects disposed between adjacent SOT devices of the plurality of SOT devices, the one or more interconnects connecting the adjacent SOT devices together.

### CROSS-REFERENCE TO RELATED APPLICATIONS

This application claims benefit of U.S. provisional patent application Ser. No. 63/521,306, filed Jun. 15, 2023, which is herein incorporated by reference.

### BACKGROUND OF THE DISCLOSURE

### Field of the Disclosure

Embodiments of the present disclosure generally relate to an integrated circuit utilizing spin orbital-spin orbital (SO-SO) logic.

### Description of the Related Art

For the past several decades, the scaling of features in integrated circuits has been a driving force behind an ever-growing semiconductor industry. Scaling to smaller and smaller features enables increased densities of functional units on the limited real estate of semiconductor chips. For example, shrinking transistor size allows for the incorporation of an increased number of memory or logic devices on a chip, lending to the fabrication of products with increased capacity.

Magneto-electric spin orbital (MESO) structures have been proposed and used recently as a new logic element, which are much more energy efficient by requiring at least 10 times lower voltage to switch than complementary metal-oxide semiconductor (CMOS) transistors, for example. However, MESO structures are difficult to manufacturing and complicated for proper biasing. If MESO structures are improperly biased, the current and voltage cannot be controlled between various portions of the device,

Furthermore, the MESO structure uses different mechanisms for input and output. The input stage uses a magnetoelectric element, typically a multiferroic material such as BiFeOs to perform charge-to-spin conversion, while the output stage uses the spin-orbit coupling, such as the inverse spin Hall effect for spin-to-charge conversion. Thus, the input and output stage have to be separated and MESO consumes larger area.

Furthermore, the input stage multiferroic material, BiFeO₃, has a large variation of the switching threshold voltage of the ferroelectric polarity. For example, a 20 nm-thick BiFeO₃ layer can be switched by a voltage varying from 0.15 V to 1.5 V. Such a large variation of the switching threshold voltage on wafer-scale is not preferred for integrated circuits.

Therefore, there is a need in the art for improved semiconductor logic.

### SUMMARY OF THE DISCLOSURE

The present disclosure generally relates to an integrated circuit utilizing spin orbital-spin orbital (SO-SO) logic. The integrated circuit comprises a plurality of SO-SO logic cells, where each SO-SO logic cell comprises a first spin orbit torque (SOT1) layer, a second spin orbit torque (SOT2) layer, and a ferromagnetic layer disposed between the SOT1 and SOT2 layer. Each SO-SO logic cell is configured for: a first current path that is in plane to a plane of the SOT1 layer, and a second current path that is perpendicular to a plane of the SOT2 layer, the second current path being configured to extend into the ferromagnetic layer. The integrated circuit further comprises a common voltage source connected to each SOT device, and one or more interconnects disposed between adjacent SOT devices of the plurality of SOT devices, the one or more interconnects connecting the adjacent SOT devices together.

In one embodiment, a device comprises a first spin orbit torque (SOT1) layer, a second spin orbit torque (SOT2) layer, and a ferromagnetic layer disposed between the SOT1 and SOT2 layer, wherein the device is configured for: a first current path that is in plane to a plane of the SOT1 layer, and a second current path that is perpendicular to a plane of the SOT2 layer, the second current path being configured to extend into the ferromagnetic layer.

In another embodiment, an integrated circuit (IC) comprises a first spin orbit torque (SOT) device comprising: a first spin orbit torque layer, a second spin orbit torque layer coupled to a first output terminal, and a ferromagnetic layer disposed between the first and second spin orbit torque layers, a second SOT device comprising: a first spin orbit torque layer coupled to a first input terminal, a second spin orbit torque layer, and a ferromagnetic layer disposed between the first and second spin orbit torque layers, and a first interconnect disposed between the first output terminal of the first SOT device and the first input terminal of the second SOT device.

In yet another embodiment, an integrated circuit (IC) comprises a plurality of spin orbit torque (SOT) devices, each SOT device comprising: a first spin orbit torque (SOT1) layer, a second spin orbit torque (SOT2) layer, a ferromagnetic layer disposed between the SOT1 and SOT2 layer; and an MgO layer disposed between the ferromagnetic layer and the SOT2, wherein each SOT device is configured for: a first current path that is in plane to a plane of the SOT1 layer, and a second current path that is perpendicular to a plane of the SOT2 layer, the second current path being configured to extend into the ferromagnetic layer, a common voltage source connected to each SOT device, and one or more interconnects disposed between adjacent SOT devices of the plurality of SOT devices, the one or more interconnects connecting the adjacent SOT devices together.

In another embodiment, an integrated circuit (IC) comprises a first spin orbit torque (SOT) device comprising: a first spin orbit torque layer coupled to an input interconnect, configured to accept an input to a neural network node, a second spin orbit torque layer coupled to an output interconnect, and a ferromagnetic layer disposed between the first and second spin orbit torque layers, configured to encode a weight, and a second SOT device comprising: a first spin orbit torque layer coupled to an input interconnect, configured to accept an input to the neural network node, a second spin orbit torque layer coupled to an output interconnect, and a ferromagnetic layer disposed between the first and second spin orbit torque layers, configured to encode a weight, wherein the output interconnects of the first and second SOT devices are coupled to a summed output interconnect.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1A illustrates a conventional magneto-electric spin orbital (MESO) structure.

FIG. 1B illustrates biasing problems within a conventional MESO transistor comprising the MESO structure of FIG. 1A.

FIG. 2A illustrates a spin orbital-spin orbital (SO-SO) logic cell, according to one embodiment.

FIG. 2B illustrates a SO-SO logic device comprising the SO-SO logic cell of FIG. 2A, according to one embodiment.

FIG. 3 illustrates a graph of output current density versus device width for the SO-SO logic device of FIG. 2B, according to one embodiment.

FIG. 4 illustrates a graph of total energy consumption per logic cell versus device width for the SO-SO logic device of FIG. 2B, according to one embodiment.

FIG. 5 shows an example neural network.

FIG. 6 shows SO-SO logic devices configured to perform a MAC (multiply-accumulate) operation of a neuron node, according to one embodiment.

FIG. 7 shows SO-SO logic devices configured to perform an activation function of a neuron node, according to one embodiment.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

In the following, reference is made to embodiments of the disclosure. However, it should be understood that the disclosure is not limited to specific described embodiments. Instead, any combination of the following features and elements, whether related to different embodiments or not, is contemplated to implement and practice the disclosure. Furthermore, although embodiments of the disclosure may achieve advantages over other possible solutions and/or over the prior art, whether or not a particular advantage is achieved by a given embodiment is not limiting of the disclosure. Thus, the following aspects, features, embodiments and advantages are merely illustrative and are not considered elements or limitations of the appended claims except where explicitly recited in a claim(s). Likewise, reference to “the disclosure” shall not be construed as a generalization of any inventive subject matter disclosed herein and shall not be considered to be an element or limitation of the appended claims except where explicitly recited in a claim(s).

The present disclosure generally relates to an integrated circuit utilizing spin orbital-spin orbital (SO-SO) logic, where a ferro-magnetic layer is used to encode a logic state, and both the input (write) and output (read) of a logic cell are based on spin orbital based mechanisms. The integrated circuit comprises a plurality of SO-SO logic cells, where each SO-SO logic cell comprises a first spin orbit torque (SOT1) layer, a second spin orbit torque (SOT2) layer, and a ferromagnetic layer disposed between the SOT1 and SOT2 layer. Each SO-SO logic cell is configured for: a first current path that is in plane to a plane of the SOT1 layer, and a second current path that is perpendicular to a plane of the SOT2 layer, the second current path being configured to extend into the ferromagnetic layer. The integrated circuit further comprises a common voltage source connected to each SOT device, and one or more interconnects disposed between adjacent SOT devices of the plurality of SOT devices, the one or more interconnects connecting the adjacent SOT devices together.

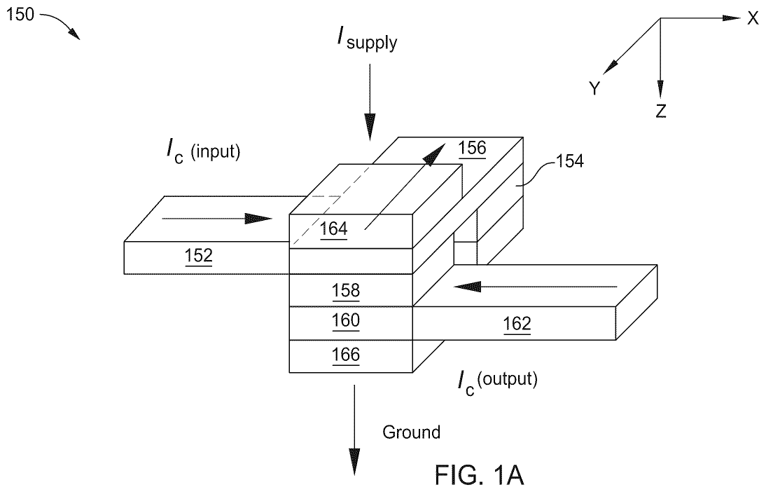

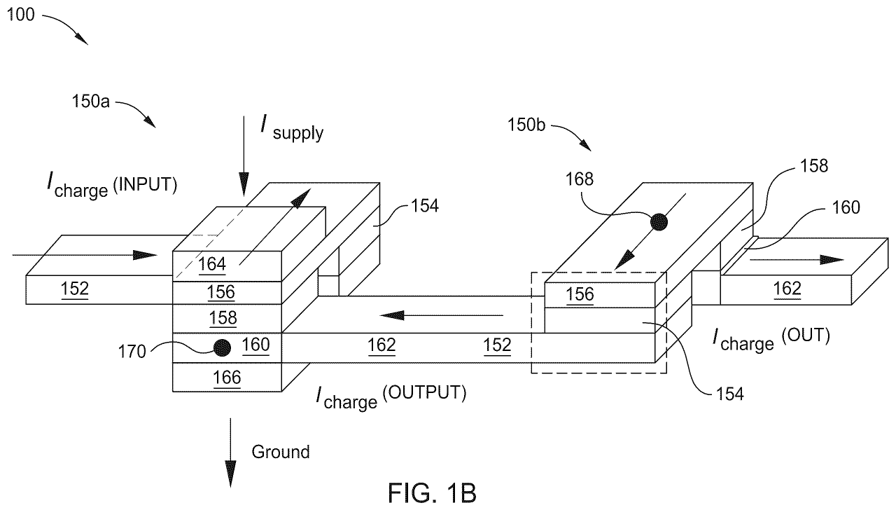

FIG. 1A illustrates a conventional magneto-electric spin orbital (MESO) structure 150. FIG. 1B illustrates a conventional MESO transistor 100 comprising one or more MESO structures 150 of FIG. 1A.

The conventional MESO structure 150 comprises a first interconnect 152 for current input (I_{c} (input)). The first interconnect 152 is coupled to a magnetoelectric material 154 such that the magnetoelectric material 154 is stacked on the first interconnect 152 in the'z-direction. The magnetoelectric material 154 is coupled to a nanomagnet or a ferromagnet 156 such that the nanomagnet 156 is stacked on the magnetoelectric material 154 in the—z-direction. The nanomagnet 156 extends in the y-direction, where the nanomagnet 156 is coupled to a first contact 164 in the—z-direction and a spin injection layer 158 in the z-direction. The spin injection layer 158 is coupled to a spin orbit coupling stack 160 such that the spin injection layer 158 is stacked on the spin orbit coupling stack 160. The spin orbit coupling stack 160 is then coupled to a second interconnect 162 in the x-direction, where the second interconnect is for current output (I_{c} (output)). The spin orbit coupling stack 160 is further coupled to a second contact 166 in the z-direction. The first contact 164 and the second contact 166 are to electronics and to power supply. The second contact 166 is further connected to ground.

In the MESO structure 150, an input current (I_{c} (input)) is provided via the first interconnect 152, which is coupled to the magnetoelectric material 154, which transduces or converts the input current into magnetism which switches the magnetization direction of the nanomagnet 156. The direction of the nanomagnet 156 represents the on/off state of the MESO structure 150. To read out the nanomagnet's 156 state, a supply current (I_{supply}) is applied perpendicular into the nanomagnet 156, which with the spin injection layer 158 induces a spin-polarized current into the spin-orbit coupling stack 160. The spin-orbit coupling stack 160 converts the spin current into a charge current which forms the current output (I_{c} (output)) that is sent to the second interconnect 162. In this case the output is flipped inverted from the input. The output of a MESO structure 150 (MESO structure 150a in FIG. 1B) is connected to the input of a second MESO structure 150 (MESO structure 150b in FIG. 1B), and multiple devices are arranged to build out various logic circuits, like shown in FIG. 1B. Note that, for simplicity, the supply current path and related contacts 164 and 166 are not shown for the second MESO structure 150b.

As shown in the MESO transistor 100 of FIG. 1B, the spin-orbit coupling stack 160 of the first MESO structure 150a has a first electrical potential point 170 and the nanomagnet 156 of the second MESO structure 150b has a second electrical potential point 168. The electrical potential of the first point 170 must be the same has the electrical potential of the second point 168. If the electrical potentials of the first point 170 and the second point 168 are not the same, current and voltage cannot be controlled within the MESO transistor 100. Thus, biasing the MESO transistor 100 is complicated.

Furthermore, the MESO structure uses different mechanisms for input and output. The input stage uses a magnetoelectric element, typically a multiferroic material such as BiFeO₃ to perform charge-to-spin conversion, while the output stage uses the spin-orbit coupling, such as the inverse spin Hall effect for spin-to-charge conversion. Thus, the input and output stage have to be separated and MESO consumes larger area.

Furthermore, the input stage multiferroic material, BiFeO₃ , has a large variation of the switching threshold voltage of the ferroelectric polarity. For example, a 20 nm-thick BiFeOs layer can be switched by a voltage varying from 0.15 V to 1.5 V. Such a large variation of the switching threshold voltage on wafer-scale is not preferred for integrated circuits.

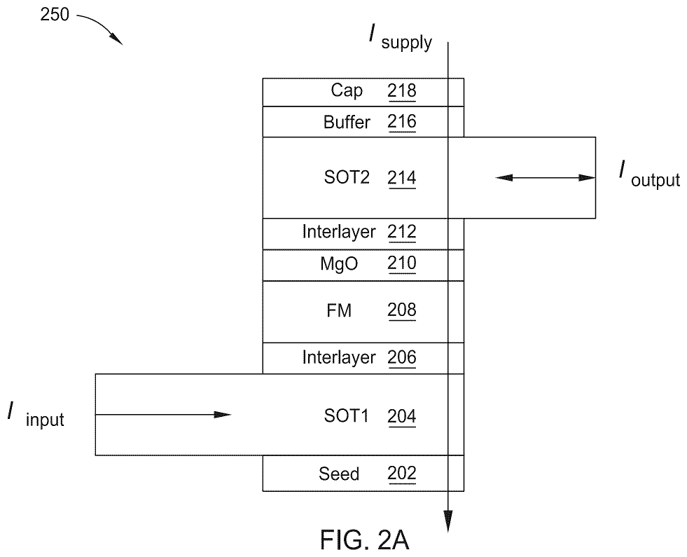

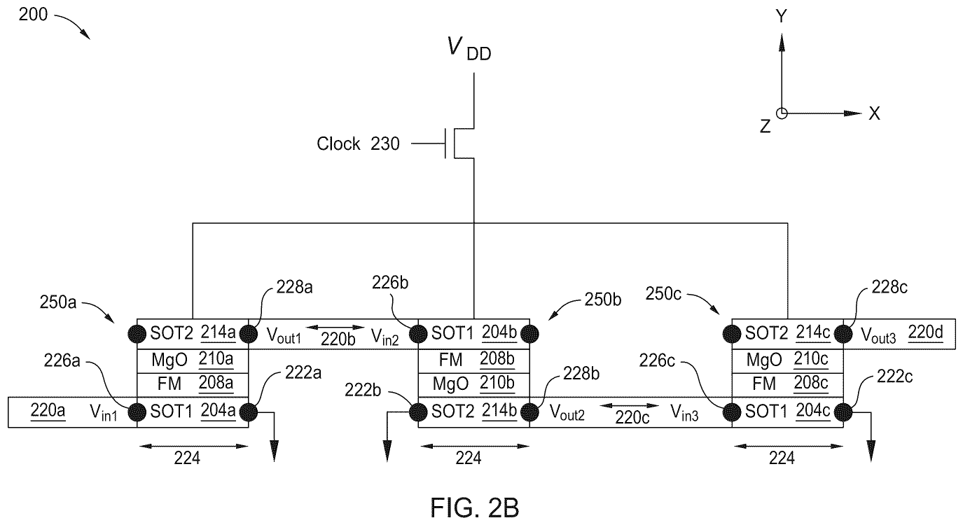

As described above, the input portion of the MESO structure relies on the magneto-electric effect for conversion (the “ME” portion of the MESO). In contrast, the present disclosure generally relates to an integrated circuit utilizing spin orbital-spin orbital (SO-SO) logic, where a ferromagnetic layer is used to encode a logic state, and both the input (write) and output (read) of a logic cell are based on spin orbital based mechanisms. FIG. 2A illustrates a spin orbital-spin orbital (SO-SO) logic cell 250, according to one embodiment. FIG. 2B illustrates an integrated circuit or SO-SO logic device 200 comprising one or more SO-SO logic cells 250a, 250b, 250c of FIG. 2A, according to one embodiment. The various layers of the SO-SO logic cell 250 are not drawn to scale, and are intended for illustrative purposes only. The SO-SO logic cells may be referred to herein as SOT devices.

In some embodiments, the SO-SO logic cell 250 comprises a seed layer 202, a first spin orbit torque (SOT) layer 204 (SOT1) disposed on the seed layer 202, a first interlayer 206 disposed on the first SOT layer 204, a ferromagnetic (FM) layer 208 disposed on the first interlayer 206, an MgO layer 210 disposed on the FM layer 208, a second interlayer 212 disposed on the MgO layer 210, a second SOT layer 214 (SOT2) disposed on the second interlayer 212, a buffer layer 216 disposed on the second SOT layer 214, and a cap layer 218 disposed on the buffer layer 216. The second SOT layer 214 is coupled to an interconnect 220a (shown in FIG. 2B), where the interconnect 220a is coupled to the first SOT layer 204 of a second SO-SO logic cell 250b (shown in FIG. 2B). Thus, multiple SO-SO logic cells 250a-250c are arranged to build out various logic circuits. The seed layer 202, interlayers 206 and 212, MgO layer 210 and cap layer 218 are optional in some embodiments. These layers may also be tuned to optimize the characteristics of the SOT layers 204, 214 (e.g., to increase the effective spin Hall angle which would improve the efficiency of the overall device). The MgO layer 210 can be generally an oxide or nitride or carbide layer besides MgO, for example, Ti, TiO, MgTi, MgTiO, TiN, and NiO.

In operation, the SO-SO logic cell is a hybrid device, relying the spin Hall effect (SHE) for the write path and inverse SHE (iSHE) for the read path. To “write” the logic state, an input current (Iᵢₙₚᵤₜ) is applied as a current-in-plane (CIP) current into the first SOT layer 204, inducing switching of the FM layer 208 via the generation of the SHE. To “read” out the state of the FM layer 208, a supply current (I_{supply}) is applied perpendicular through the SO-SO logic cell 250, as a current-perpendicular-to-plane (CPP) into the second SOT layer 214. The current through the FM layer 208 becomes spin polarized and such spin current will inject into the second SOT layer 214, which, via the iSHE, there will be an electrical voltage induced in the second SOT layer 214 that is proportional to the spin current magnitude. Such voltage potential will generate a charge current which forms the current output (Iₒᵤₜₚᵤₜ) if a load is connected. Iₒᵤₜₚᵤₜ is thus reflective of the magnetization of the FM layer 208 which encodes the logic state. Thus, rather than utilizing a magneto-electric effect like the MESO structure 150 and the MESO transistor 100 of FIGS. 1A-1B, the SO-SO logic cell 250 utilizes spin orbit based effects for both the “write” and “read” of its logic state encoded in the FM layer 208.

As stated above, the SO-SO device uses the same spin-orbit coupling mechanism for charge-to-spin and spin-to-charge conversion. Thus, the input stage and output stage can be stacked together, saving device footprint and increasing integration density.

As noted above, the SO-SO logic cell 250 is configured for a first current path (Iᵢₙₚᵤₜ) that is in plane to a plane of the first SOT layer 204, and a second current path (I_{supply}) that is perpendicular to a plane of the second SOT layer 214, the second current path being configured to extend into the FM layer 208. In some embodiments, the second current path is configured to extend into the first SOT layer 204 as well. For example, when writing data, the SO-SO logic device 200 is configured to receive an input current (at terminal marked as V_{in[N]} shown in FIG. 2B, N denoting the individual logic cell that can be interconnected) at the first current path, and the first SOT layer 204 is configured to affect a direction of a magnetization of the FM layer 208 due to the input current. When reading a logic state encoded by the magnetization of the FM layer 208, the SO-SO logic device 200 is configured to receive a supply current (I_{supply}) at the second current path, and to generate, via the second SOT layer 214, an output current (Iₒᵤₜₚᵤₜ) (V_{out [N]} shown in FIG. 2B) responsive to a direction of the magnetization of the FM layer 208.

The seed layer 202 may be a multilayer structure comprising layer combinations of: (1) one or more amorphous conditioning layers, such as NiTa, NiW, NiFeTa, NiFeW, etc.; (2) an RuAl texturing layer; (3) an MgO layer; and (4) NiₓRu₍₁₋ₓ₎Al (where x is from zero to 1) alloys, any crystalline or nanocrystalline, nonmagnetic element, or an alloy material with an equivalent BCC or B2 lattice parameter in the range of 2.93 Å to 3.03 Å, which doesn't react with the SOT and doesn't contain heavy metals. In some embodiments, the seed layer 202 may be a textured seed layer comprising an amorphous/crystalline migration layer and a seed layer combination, like NiFe Ta/RuAl/NiFeGe, NiTa/NiFeGe, NiTa/NiFeGe/Ge, NiFeTa/RuAl/CuGe, NiTa/NiₓRu₍₁₋ₓ₎Al/NiGe, etc., (“/” denoting layer separation).

The first interlayer 206, the second interlayer 212, and the buffer layer 216 may each individually comprise NiₓRu₍₁₋ₓ₎Al (where x is from zero to 1) alloys, any crystalline or nanocrystalline, nonmagnetic element, or an alloy material with an equivalent BCC or B2 lattice parameter in the range of 2.93 Å to 3.03 Å, which doesn't react with the SOT and doesn't contain heavy metals. In some embodiments, the first interlayer 206, the second interlayer 212, and the buffer layer 216 may each individually comprise amorphous/crystalline layers or combinations of layers, such as Ge, NiFeGe, NiGe, CuGe, Ge/NiAl, Ge/RuAl, RuGe, NiAlGe, GeN, NiFeGeN, NiAlGeN, or RuAlGe.

The cap layer 218 may comprise MgO, any material of the first interlayer 206, the second interlayer 212, or the buffer layer 216, an amorphous high resistant material, or layer combinations thereof, such as a multilayer stack of MgO and NiFeGe or other high resistance materials. The cap layer 218 may be a textured cap layer 218 comprising combination of high resistance crystalline or amorphous materials like TiO, TiN, MgO, composites like MgOTiO, NiFeGe, or Ge. The FM layer 208 may comprise bcc or Heusler FM materials, such as CoFe, CoFeMnGe, CoFeGe, CoFeAl, CoFeSi, etc.

In some embodiments, the first SOT layer 204 and the second SOT layer 214 each individually comprises a topological insulator material. The SOT layer 214 may comprise at least one of BiSb, a topological insulator, a topological half-Heusler alloy like YPtBi, and a weakly oxidized heavy metal. In some embodiments, the topological insulator material can be BiSb with (012) orientation to achieve the highest spin Hall angle (current-spin conversion efficiency). The BiSb material has been shown to have a giant spin Hall angle as large as 52 and an inverse spin Hall angle as large as 61, and thus can be applied to the first SOT layer 204 and the second SOT layer 214. Furthermore, the BiSb layer can be epitaxially grown by using an appropriate seed or interlayer, thus greatly reducing the variation of the switching current density for the FM layer on wafer scale. The first SOT layer 204 and the second SOT layer 214 is each individually disposed in contact with an appropriate buffer layer 216 and/or and interlayer 206, 212 to minimize diffusion and roughness. The first SOT layer 204 and the second SOT layer 214 may each individually comprise undoped BiSb or doped BiSbX, where the dopant is less than about 10 at. %, and where X is extracted from elements which don't readily interact with Bi, such as B, N, AI, Si, Ti, V, Ni, Cu, Ge, Y, Zr, Ru, Mo, Ag, Hf, W, Re, Ir, or in alloy combinations with one or more of aforementioned elements, like CuAg, CuNi, RuGe, etc. The benefit of the high spin Hall angle of the material of the first and second SOT layers 204, 214 is utilized for both writing and reading of the logic state or value encoded in the FM layer 208.

FIG. 2B illustrates a SO-SO logic device 200 comprising one or more SO-SO logic cells 250a, 250b, 250c of FIG. 2A, according to one embodiment. The SO-SO logic device 200 illustrates three SO-SO logic cells 250a, 250b, 250c; however, the SO-SO logic device 200 may comprise any number of SO-SO logic cells 250, and they may be interconnected in other arrangements than the one shown. Additionally, one or more layers of each of the SO-SO logic cells 250a, 250b, 250c are not shown for clarity purposes only. The SO-SO logic device 200 may be referred to herein as an integrated circuit (IC).

The first SO-SO logic cell 250a comprises a first SOT layer 204a coupled to a first interconnect 220a, the FM layer 208a disposed on the first SOT layer 204a, the MgO layer 210a disposed on the FM layer 208a, and the second SOT layer 214a disposed on the MgO layer 210a. The first interconnect 220aprovides a first voltage input (Vᵢₙ₁) to an input terminal 226a of the first SOT layer 204a. A second interconnect 220b is coupled to the second SOT layer 214a at an output terminal 228a, which provides a first voltage output (Vₒᵤₜ₁). The second interconnect 220b is also coupled to the first SOT layer 204b of the second SO-SO logic cell 250b at an input terminal 226b, which provides a second voltage input (Vᵢₙ₂). The first SOT layer 204a is further connected to a ground terminal 222a.

Similarly, the second SO-SO logic cell 250b comprises the FM layer 208b disposed on the first SOT layer 204b, the MgO layer 210b disposed on the FM layer 208b, and the second SOT layer 214b disposed on the MgO layer 210b. The second SOT layer 214b is coupled to a third interconnect 220c at an output terminal 228b, which provides a second voltage output (Vₒᵤₜ₂). The third interconnect 220c is coupled to the first SOT layer 204c of the second SO-SO logic cell 250c at an input terminal 226c, which provides a third voltage input (Vᵢₙ₃). The second SOT layer 214b is further connected to a ground terminal 222b.

The third SO-SO logic cell 250c comprises the FM layer 208c disposed adjacent to the first SOT layer 204c, the MgO layer 210c disposed on the FM layer 208c, and the second SOT layer 214c disposed on the MgO layer 210c. The second SOT layer 214c is coupled to a fourth interconnect 220d at an output terminal 228c, which provides both a third voltage output (Vₒᵤₜ₃). The fourth interconnect 220d is coupled to the first SOT layer of a fourth SO-SO logic cell (not shown) at an input terminal (not shown). The first SOT layer 204c is further connected to a ground terminal 222c.

Each SO-SO logic cell 250a, 250b, 250c has a width 224 in the x-direction of about 5 nm to about 20 nm, which is defined by logic design rules based on available semiconductor industry process nodes. The first, second, and third interconnects 220a, 220b, 220c each individually comprises Cu, for example. The first, second, and third interconnects 220a, 220b, 220c each individually has a width in the x-direction of about 5 nm to about 100 nm, again defined by logic design rule based on density requirements.

A supply voltage (VDD) is connected to each of the SO-SO logic cells 250a, 250b, 250c. A clocking control element or clock 230 may be connected between each of the SO-SO logic cells 250a, 250b, 250c and the supply voltage. The MgO layer 210a, 210b, 210c disposed between the FM layer 208a, 208b , 208cand the second SOT layer 214a, 214b, 214c of each SO-SO logic cell 250a, 250b, 250c (collectively referred to herein as SO-SO logic cell 250) enhances the first, second, and third voltage outputs, and further makes sure that first, second, and third voltage outputs are higher (smaller) than the voltage input of the next SO-SO logic cell. The MgO layers 210a, 210b, and 210c also help prevent back-flow of the pure spin current due to the output current. Each first SOT layer 204a, 204b, 204c (collectively referred to herein as first SOT layer 204) and each second SOT layer 214a, 214b, 214c (collectively referred to herein as second SOT layer 214) are correctly biased in adjacent SO-SO logic cell to make sure that their middle potentials are the same, such that there is no unexpected current between the voltage outputs and the voltage inputs.

For each SO-SO logic cell 250a, 250b, 250c, there are three energy terms: a pillar energy due to the supply current and one from each of the SOT layers 204, 214. When a topological insulator material, such as BiSb (012) with a giant spin Hall (52) and inverse spin Hall angle (61), is utilized in the first and second SOT layers 204, 214, the hybrid SO-SO logic cell 250 can reach a current density greater than about 1*10⁶ A/cm², which is sufficiently high enough to drive the next stage of SO-SO logic cell input. In this situation, the power consumption for SOT switching of the FM layer is significantly smaller than the pillar energy. The total energy required is essentially consistent and mainly driven by pillar energy from transistor drive current. The estimated required energy of about 50 aJ of the SO-SO logic device 200 is less than that of a conventional CMOS transistor, which has an estimated required energy of about 300 aJ. Thus, the SO-SO logic device 200 vastly reduces energy consumption.

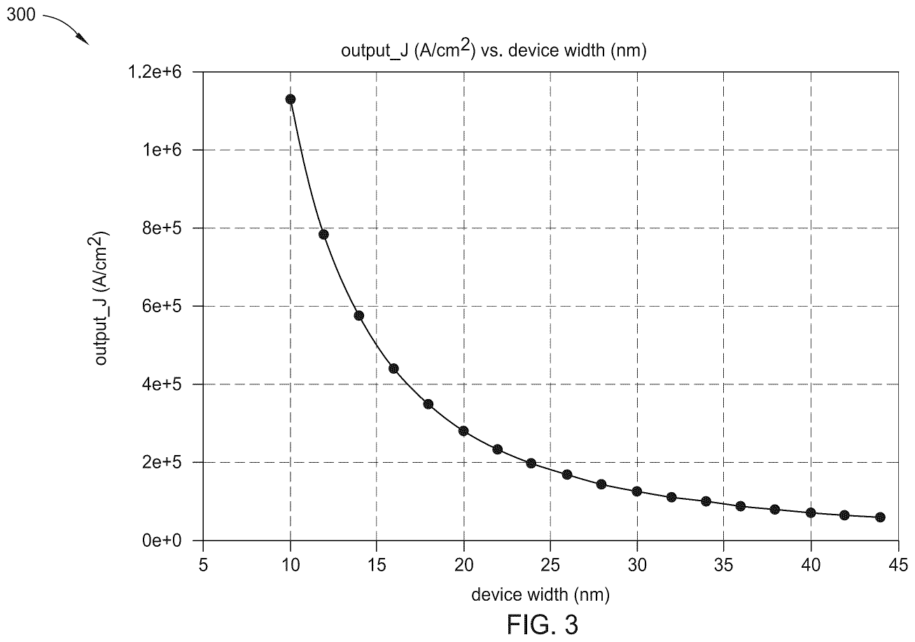

FIG. 3 illustrates a graph 300 of current density in A/cm2 versus device width in nm for the SO-SO logic device 200 of FIG. 2B, according to one embodiment. As shown, when each SO-SO logic cell 250 has a width between about 8 nm to about 20 nm, the SO-SO logic device 200 achieves a current density output between about 3*10⁵ A/cm² and 1*10⁶ A/cm², which is sufficiently high enough to drive the next stage or SO-SO logic cell input.

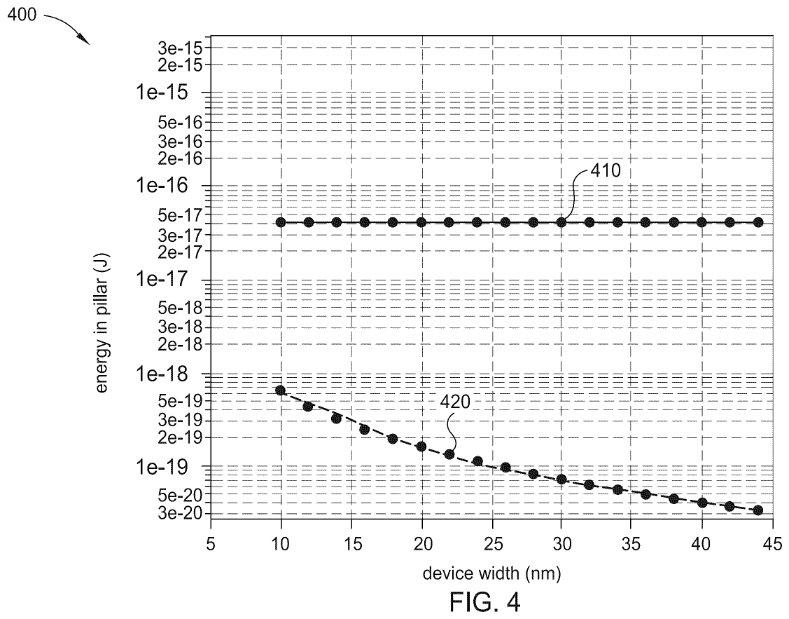

FIG. 4 illustrates a graph 400 of total energy in J per logic cell versus device width in nm for the SO-SO logic device 200 of FIG. 2B, according to one embodiment. Line 420 represents the total energy from each SOT layer 204, 214 individually. Line 410 represents the pillar energy and total energy consumption combined (lines here are overlapped and are essentially the same, indicating the total energy is mainly driven by pillar energy from transistor drive current). As shown, when each SO-SO logic cell 250 has a width between about 8 nm to about 20 nm, the SO-SO logic device 200 achieves an estimated energy requirement of about 50 aJ (1 aJ=10⁻¹⁸ J, unit in Y-axis), which is significantly less than that of a conventional CMOS transistor.

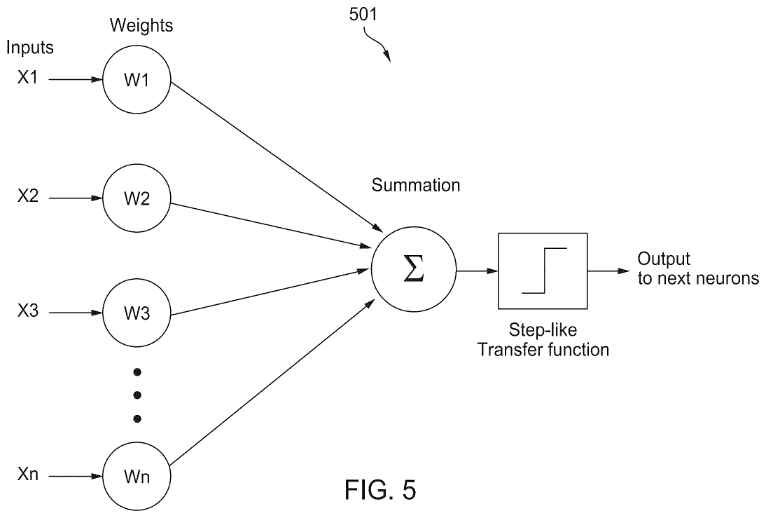

FIGS. 5-7 illustrate example embodiments of SO-SO logic devices in neural network configurations. FIG. 5 shows an example neural network 500. A neural node 501 is shown, where it takes a summation of input X₁ . . . . Xₙ multiplied by weights W₁ . . . . Wₙ. This is also referred to as a multiply-accumulate (MAC) operation. Besides this MAC operation, the node feeds the MAC output to an activation function to provide a final output of the node. The activation function, which may be a step-like function such as ReLU (rectified linear unit) activation function, will generate an output to node(s) in the next layer(s) of the neural network. The output in some embodiments is dependent on whether the result of the MAC operation meets a threshold in the step-like function (activated vs. not activated).

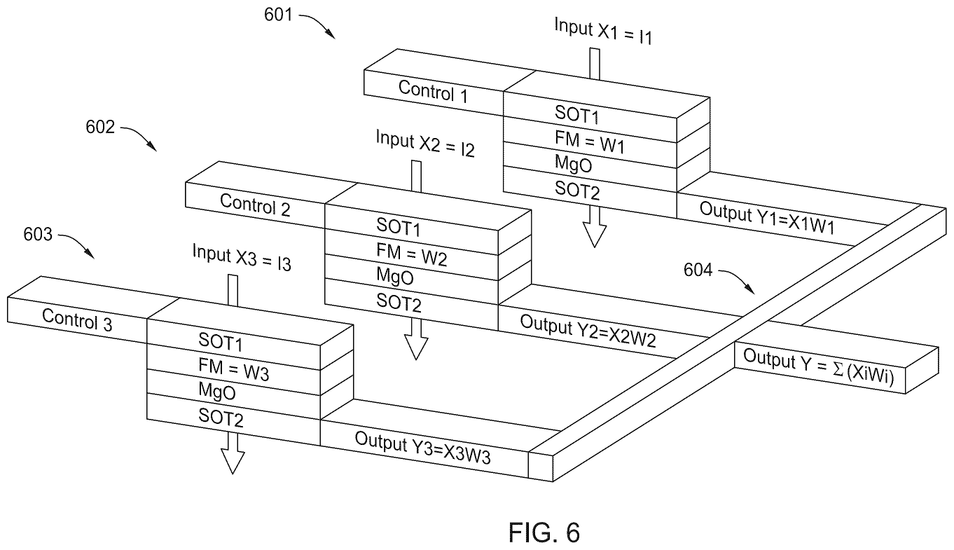

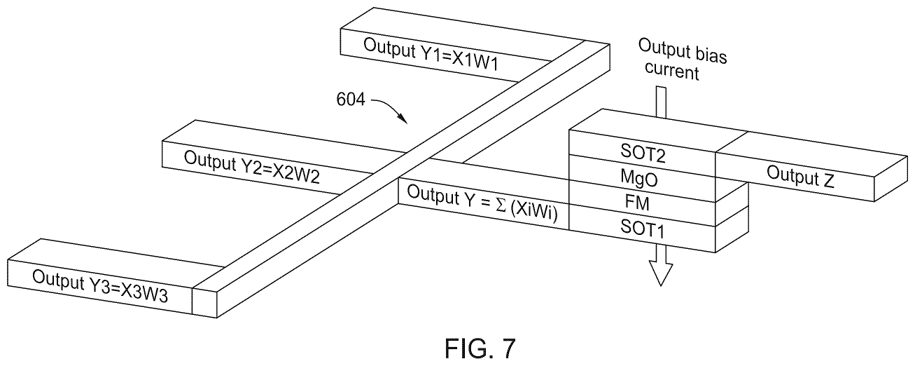

The MAC operation and the activation function constitute two core functions of the neuron node, and FIGS. 6-7 show how SO-SO logic devices can be used to implement each function. FIG. 6 shows SO-SO logic devices configured to perform a MAC operation, according to one embodiment. In this example, each of SO-SO logic devices 601-603 can be fabricated and configured as described previously in FIGS. 2A-2B. Here, the input bias currents I₁₋ₙ (corresponding to I_{supply} in FIG. 2A) represent neural network input X₁₋ₙ in FIG. 5, i.e., the input values into the neuron node. The magnetization states in the FM layers of the SO-SO logic devices 601-603 encode the neural network weights (W₁₋ₙ in FIG. 5). The magnetization (M) states can be either +M (positive), −M (negative), or an arbitrary analog value in between, depending on the domain wall position in the FM layer. In some embodiments, the magnetization states can be controlled by the setting current pulse width or amplitude via the input current labeled as Controlin (corresponding to Iᵢₙₚᵤₜ in FIG. 2A). In this manner, each SO-SO logic device 601-603 performs the logic multiplication operation of an input Xₙ times a weight Wₙ. As further shown, the results of the devices 601-603 (Y₁₋ₙ) are then summed at the interconnect junction 604. Thus, the total output current is Y=Σ(XᵢWᵢ), representing the MAC operation shown in FIG. 5. In this manner, the SO-SO logic devices can be configured together to perform the MAC operation.

FIG. 7 shows SO-SO logic devices configured to perform the activation function of a neuron node, according to one embodiment. The figure shows the continuation of FIG. 6, with the summed total output current Y=Σ(XᵢWᵢ) being fed to an output SO-SO logic device 701, which in one embodiment has an abrupt threshold current density for switching of its FM layer. This can be realized by reducing the size of the FM layer of the SO-SO logic device 710 so that the magnetization switching mechanism is coherent switching. Thus, this output SO-SO logic device 701 works logically as a step-like transfer function shown in FIG. 5. In addition, the output bias current of the output SO-SO logic device 701 can be set so that the output Z can be high enough to drive the next stage. This final output Z then can be fetched to the next neuron layer(s). In this manner, a SO-SO logic device can be configured to perform the activation function operation. Taken together, FIGS. 6-7 show how multiple SO-SO logic devices can be configured to perform the functions of a neuron node in a neural network.

Thus, by utilizing a SO-SO logic device comprising a plurality of SO-SO logic cells, each SO-SO logic cell comprising a first SOT layer and a second SOT layer, the SO-SO logic device effectively functions as a semiconductor device capable of performing logic operations while reducing energy consumption. Furthermore, the simplified structure of the SO-SO logic device has scaling advantages while maintaining a low energy consumption, making the SO-SO logic device mass-production friendly while easy to bias.

In one embodiment, a device comprises a first spin orbit torque (SOT1) layer, a second spin orbit torque (SOT2) layer, and a ferromagnetic layer disposed between the SOT1 and SOT2 layer, wherein the device is configured for: a first current path that is in plane to a plane of the SOT1 layer, and a second current path that is perpendicular to a plane of the SOT2 layer, the second current path being configured to extend into the ferromagnetic layer.

The device is further configured to receive an input current at the first current path, and wherein the SOT1 layer is configured to affect a direction of a magnetization of the ferromagnetic layer due to the input current. The device is further configured to receive a supply current at the second current path, and to generate, via the SOT2 layer, an output current responsive to a direction of the magnetization of the ferromagnetic layer. The device further comprises an MgO layer disposed between the ferromagnetic layer and the second spin orbit torque layer. The device has a width between about 8 nm to about 20 nm. The first SOT layer and the second SOT layer each individually comprises undoped BiSb. The first SOT layer and the second SOT layer each individually comprises doped BiSbX, where the dopant is less than about at. 10%, and where X is a material selected from the group consisting of: B, N, AI, Si, Ti, V, Ni, Cu, Ge, Y, Zr, Ru, Mo, Ag, Hf, Re, W, and Ir. The first SOT layer and the second SOT layer each individually has a (012) orientation. An integrated circuit comprising the device. The first SOT layer and the second SOT layer each individually comprises YPtBi.

In another embodiment, an integrated circuit (IC) comprises a first spin orbit torque (SOT) device comprising: a first spin orbit torque layer, a second spin orbit torque layer coupled to a first output terminal, and a ferromagnetic layer disposed between the first and second spin orbit torque layers, a second SOT device comprising: a first spin orbit torque layer coupled to a first input terminal, a second spin orbit torque layer, and a ferromagnetic layer disposed between the first and second spin orbit torque layers, and a first interconnect disposed between the first output terminal of the first SOT device and the first input terminal of the second SOT device.

The first SOT device further comprises an MgO layer disposed between the ferromagnetic layer and the second spin orbit torque layer, and the second SOT device further comprises an MgO layer disposed between the ferromagnetic layer and the second spin orbit torque layer. The second spin orbit torque layer of the second SOT device is coupled to a second output terminal, and wherein the device further comprises: a third SOT device comprising a first spin orbit torque layer coupled to a second input terminal, a second spin orbit torque layer, and a ferromagnetic layer disposed between the first and spin orbit torque layers, and a second interconnect disposed between the second output terminal of the second SOT device and the second input terminal of the third SOT device. The first SOT layer and the second SOT layer each individually comprises YPtBi.

The IC further comprises a common voltage source for the first, second, and third SOT devices, and a clocking control element between the voltage source and the first, second, and third SOT devices. The first spin orbit torque layer of the first SOT device is connected to a first ground terminal, and wherein the second spin orbit torque layer of the second SOT device is connected to a second ground terminal. The first spin orbit torque layer of the first SOT device, the second spin orbit torque layer of the first SOT device, the first spin orbit torque layer of the second SOT device, and the second spin orbit torque layer of the second SOT device each individually comprises BiSb. The first SOT device and the second SOT device each individually has a width between about 8 nm to about 20 nm. The first SOT device is configured for: a first current path that is in plane to a plane of the first spin orbit torque layer, and a second current path that is perpendicular to a plane of the second spin orbit torque layer, the second current path being configured to extend into the ferromagnetic layer. The second SOT device is configured for: a first current path that is in plane to a plane of the first spin orbit torque layer, and a second current path that is perpendicular to a plane of the second spin orbit torque layer, the second current path being configured to extend into the ferromagnetic layer.

In yet another embodiment, an integrated circuit (IC) comprises a plurality of spin orbit torque (SOT) devices, each SOT device comprising: a first spin orbit torque (SOT1) layer, a second spin orbit torque (SOT2) layer, a ferromagnetic layer disposed between the SOT1 and SOT2 layer; and an MgO layer disposed between the ferromagnetic layer and the SOT2, wherein each SOT device is configured for: a first current path that is in plane to a plane of the SOT1 layer, and a second current path that is perpendicular to a plane of the SOT2 layer, the second current path being configured to extend into the ferromagnetic layer, a common voltage source connected to each SOT device, and one or more interconnects disposed between adjacent SOT devices of the plurality of SOT devices, the one or more interconnects connecting the adjacent SOT devices together.

Each SOT device is further configured to receive an input current at the first current path, and wherein the SOT1 layer is configured to affect a direction of a magnetization of the ferromagnetic layer due to the input current. Each SOT device is further configured to receive a supply current at the second current path, and to generate, via the SOT2 layer, an output current responsive to a direction of the magnetization of the ferromagnetic layer. The first SOT layer and the second SOT layer each individually comprises YPtBi.

In another embodiment, an integrated circuit (IC) comprises a first spin orbit torque (SOT) device comprising: a first spin orbit torque layer coupled to an input interconnect, configured to accept an input to a neural network node, a second spin orbit torque layer coupled to an output interconnect, and a ferromagnetic layer disposed between the first and second spin orbit torque layers, configured to encode a weight, and a second SOT device comprising: a first spin orbit torque layer coupled to an input interconnect, configured to accept an input to the neural network node, a second spin orbit torque layer coupled to an output interconnect, and a ferromagnetic layer disposed between the first and second spin orbit torque layers, configured to encode a weight, wherein the output interconnects of the first and second SOT devices are coupled to a summed output interconnect.

The IC further comprises a third SOT device, the third SOT device comprising: a first spin orbit torque layer coupled to the summed output interconnect, a second spin orbit torque layer coupled to an output interconnect for the third SOT device, and a ferromagnetic layer disposed between the first and second spin orbit torque layers, configured to encode a threshold value of an activation function. The first SOT layer and the second SOT layer each individually comprises YPtBi.

While the foregoing is directed to embodiments of the present disclosure, other and further embodiments of the disclosure may be devised without departing from the basic scope thereof, and the scope thereof is determined by the claims that follow.

What is claimed is:

1. A device comprising:
a first spin orbit torque (SOT1) layer;
a second spin orbit torque (SOT2) layer; and
a ferromagnetic layer disposed between the SOT1 and SOT2 layer;
wherein the device is configured for:
a first current path that is in plane to a plane of the SOT1 layer, and
a second current path that is perpendicular to a plane of the SOT2 layer, the second current path being configured to extend into the ferromagnetic layer.

2. The device of claim 1, wherein the device is further configured to receive an input current at the first current path, and wherein the SOT1 layer is configured to affect a direction of a magnetization of the ferromagnetic layer due to the input current.

3. The device of claim 1, wherein the device is further configured to receive a supply current at the second current path, and to generate, via the SOT2 layer, an output current responsive to a direction of the magnetization of the ferromagnetic layer.

4. The device of claim 1, further comprising an MgO layer disposed between the ferromagnetic layer and the SOT2 layer.

5. The device of claim 1, wherein the device has a width between about 8 nm to about 20 nm.

6. The device of claim 1, wherein the SOT1 layer and the SOT2 layer each individually comprises undoped BiSb.

7. The device of claim 1, wherein the SOT1 layer and the SOT2 layer each individually comprises doped BiSbX, where the dopant is less than about at 0.10%, and where X is a material selected from the group consisting of: B, N, AI, Si, Ti, V, Ni, Cu, Ge, Y, Zr, Ru, Mo, Ag, Hf, Re, W, and Ir.

8. The device of claim 1, wherein the first SOT layer and the second SOT layer each individually has a (012) orientation.

9. The device of claim 1, wherein the first SOT layer and the second SOT layer each individually comprises YPtBi.

10. An integrated circuit comprising the device of claim 1.

11. An integrated circuit (IC) comprising:
a first spin orbit torque (SOT) device comprising:
a first spin orbit torque layer;
a second spin orbit torque layer coupled to a first output terminal; and
a ferromagnetic layer disposed between the first and second spin orbit torque layers;
a second SOT device comprising:
a first spin orbit torque layer coupled to a first input terminal;
a second spin orbit torque layer; and
a ferromagnetic layer disposed between the first and second spin orbit torque layers; and
a first interconnect disposed between the first output terminal of the first SOT device and the first input terminal of the second SOT device.

12. The IC of claim 11, wherein:
the first SOT device further comprises an MgO layer disposed between the ferromagnetic layer and the second spin orbit torque layer; and
the second SOT device further comprises an MgO layer disposed between the ferromagnetic layer and the second spin orbit torque layer.

13. The IC of claim 12, wherein the second spin orbit torque layer of the second SOT device is coupled to a second output terminal, and wherein the device further comprises:
a third SOT device comprising a first spin orbit torque layer coupled to a second input terminal;
a second spin orbit torque layer; and
a ferromagnetic layer disposed between the first and spin orbit torque layers; and
a second interconnect disposed between the second output terminal of the second SOT device and the second input terminal of the third SOT device.

14. The IC of claim 13, further comprising a common voltage source for the first, second, and third SOT devices, and a clocking control element between the voltage source and the first, second, and third SOT devices.

15. The IC of claim 11, wherein the first spin orbit torque layer of the first SOT device is connected to a first ground terminal, and wherein the second spin orbit torque layer of the second SOT device is connected to a second ground terminal.

16. The IC of claim 11, wherein the first spin orbit torque layer of the first SOT device, the second spin orbit torque layer of the first SOT device, the first spin orbit torque layer of the second SOT device, and the second spin orbit torque layer of the second SOT device each individually comprises BiSb.

17. The IC of claim 11, wherein the first SOT device and the second SOT device each individually has a width between about 8 nm to about 20 nm.

18. The IC of claim 11, wherein the first SOT device is configured for:
a first current path that is in plane to a plane of the first spin orbit torque layer, and
a second current path that is perpendicular to a plane of the second spin orbit torque layer, the second current path being configured to extend into the ferromagnetic layer,
wherein the second SOT device is configured for:
a first current path that is in plane to a plane of the first spin orbit torque layer, and
a second current path that is perpendicular to a plane of the second spin orbit torque layer, the second current path being configured to extend into the ferromagnetic layer.

19. The IC of claim 11, wherein the first SOT layer and the second SOT layer each individually comprises YPtBi.

20. An integrated circuit (IC) comprising:
a plurality of spin orbit torque (SOT) devices, each SOT device comprising:
a first spin orbit torque (SOT1) layer;
a second spin orbit torque (SOT2) layer;
a ferromagnetic layer disposed between the SOT1 and SOT2 layer; and
an MgO layer disposed between the ferromagnetic layer and the SOT2,
wherein each SOT device is configured for:
a first current path that is in plane to a plane of the SOT1 layer, and
a second current path that is perpendicular to a plane of the SOT2 layer, the second current path being configured to extend into the ferromagnetic layer;
a common voltage source connected to each SOT device; and
one or more interconnects disposed between adjacent SOT devices of the plurality of SOT devices, the one or more interconnects connecting the adjacent SOT devices together.

21. The IC of claim 20, wherein each SOT device is further configured to receive an input current at the first current path, and wherein the SOT1 layer is configured to affect a direction of a magnetization of the ferromagnetic layer due to the input current.

22. The device of claim 20, wherein each SOT device is further configured to receive a supply current at the second current path, and to generate, via the SOT2 layer, an output current responsive to a direction of the magnetization of the ferromagnetic layer.

23. The device of claim 20, wherein the first SOT layer and the second SOT layer each individually comprises YPtBi.

24. An integrated circuit (IC), comprising:
a first spin orbit torque (SOT) device comprising:
a first spin orbit torque layer coupled to an input interconnect, configured to accept an input to a neural network node;
a second spin orbit torque layer coupled to an output interconnect; and
a ferromagnetic layer disposed between the first and second spin orbit torque layers, configured to encode a weight; and
a second SOT device comprising:
a first spin orbit torque layer coupled to an input interconnect, configured to accept an input to the neural network node;
a second spin orbit torque layer coupled to an output interconnect; and
a ferromagnetic layer disposed between the first and second spin orbit torque layers, configured to encode a weight;
wherein the output interconnects of the first and second SOT devices are coupled to a summed output interconnect.

25. The IC of claim 24, further comprising a third SOT device, the third SOT device comprising:
a first spin orbit torque layer coupled to the summed output interconnect;
a second spin orbit torque layer coupled to an output interconnect for the third SOT device; and
a ferromagnetic layer disposed between the first and second spin orbit torque layers, configured to encode a threshold value of an activation function.

26. The IC of claim 24, wherein the first SOT layer and the second SOT layer each individually comprises YPtBi.
